(19) United States
(12) Patent Application Publication
(10) Pub. No.: US 2010/0036630 A1
(43) Pub. Date: Feb. 11, 2010

(54) SYSTEM AND METHOD FOR SIGNAL MEASUREMENT

(75) Inventors: JUI-HSIUNG HO, Tu-Cheng (TW); WANG-DING SU, Tu-Cheng (TW); CHI-REN KUO, Tu-Cheng (TW); HUNG CHAO, Tu-Cheng (TW); YUNG-CHENG HUNG, Tu-Cheng (TW); PO-KAI HUANG, Tu-Cheng (TW)

Correspondence Address: PCE INDUSTRY, INC.;ATT. Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/250,485

(22) Filed: Oct. 13, 2008

(30) Foreign Application Priority Data
Aug. 11, 2008 (CN) 200810303658.4

(51) Int. Cl. G01R 13/02

(52) U.S. Cl. 702/67

(57) ABSTRACT

A signal measurement method includes receiving a signal from a signal generating module; displaying a wave of the signal; reading a reference parameter of the signal, and adjusting the wave according to the reference parameter; measuring the signal according to the wave after adjustment; and displaying the measurement result.

### BACKGROUND

1. Technical Field

Embodiments of the present disclosure relate to measuring systems and methods, and particularly to a system and a method for measuring signals.

2. Description of the Related Art

Currently, oscilloscopes are commonly used for measuring and displaying cyclic waves of electronic signals. When various signals are to be measured using an oscilloscope, it is necessary to set a plurality of relevant knobs or switches individually to pre-determined positions in advance, and manually adjust the scales of displayed graphs. It is inconvenient and time consuming for operators performing numerous samples of signals to be measured.

What is needed, therefore, is to provide a more efficient system and method for signal measurement.

### BRIEF DESCRIPTION OF THE DRAWINGS

FIG. 1 is a block diagram of one embodiment of a signal measuring system.

FIG. 2 is a flowchart of one embodiment of a signal measuring method.

### DETAILED DESCRIPTION

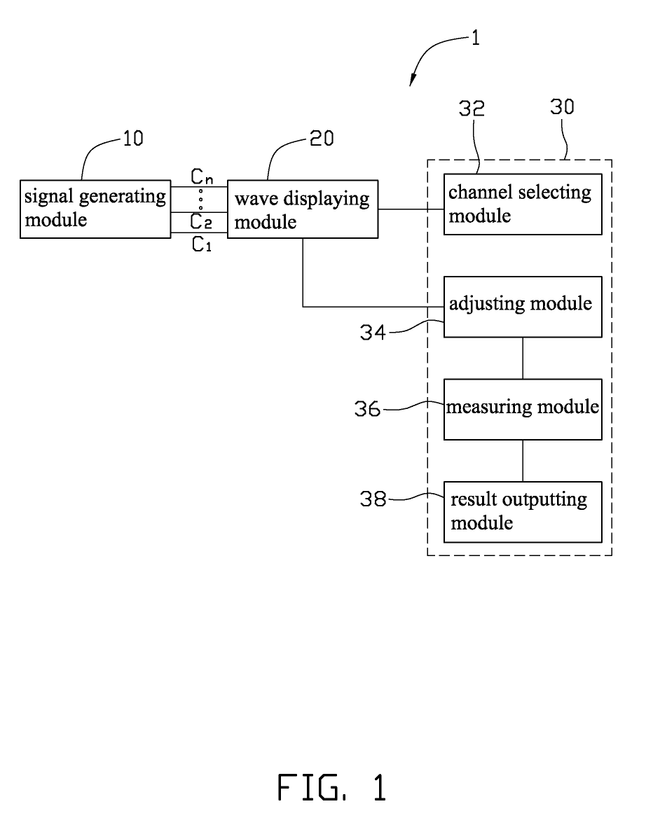

FIG. 1 is a block diagram of one embodiment of a signal measuring system 1. The system 1 includes a signal generating module 10, a wave displaying module 20, and a controlling module 30 connected in series. The wave displaying module 20 is connected to the signal generating module 10 via a plurality of signal channels C1, C2 . . . Cn. The controlling module 30 includes a channel selecting module 32, an adjusting module 34, a measuring module 36, and a result outputting module 38. The channel selecting module 32 and the adjusting module 34 are connected to the wave displaying module 20. The adjusting module 34, the measuring module 36, and the result outputting module 38 are connected in series.

The signal generating module 10 is an electronic device which generates signals to be measured, such as an RGB signal, a timing signal, and a synchronization signal, for example. The wave displaying module 20 is an oscilloscope, in one embodiment, which receives a generated signal from the signal generating module 10 via a corresponding signal channel, such as the signal channel C1, and displays a wave graph of the generated signal on a screen thereof.

The controlling module 30 is configured for sampling and measuring the generated signal automatically. The controlling module 30 is located in a computer system (not shown) in which an operating system is used to control the controlling module 30. The channel selecting module 32 is configured to select a signal channel to transmit a required signal to be measured. A predetermined number of samples of each signal to be measured is stored in the measuring module 36.

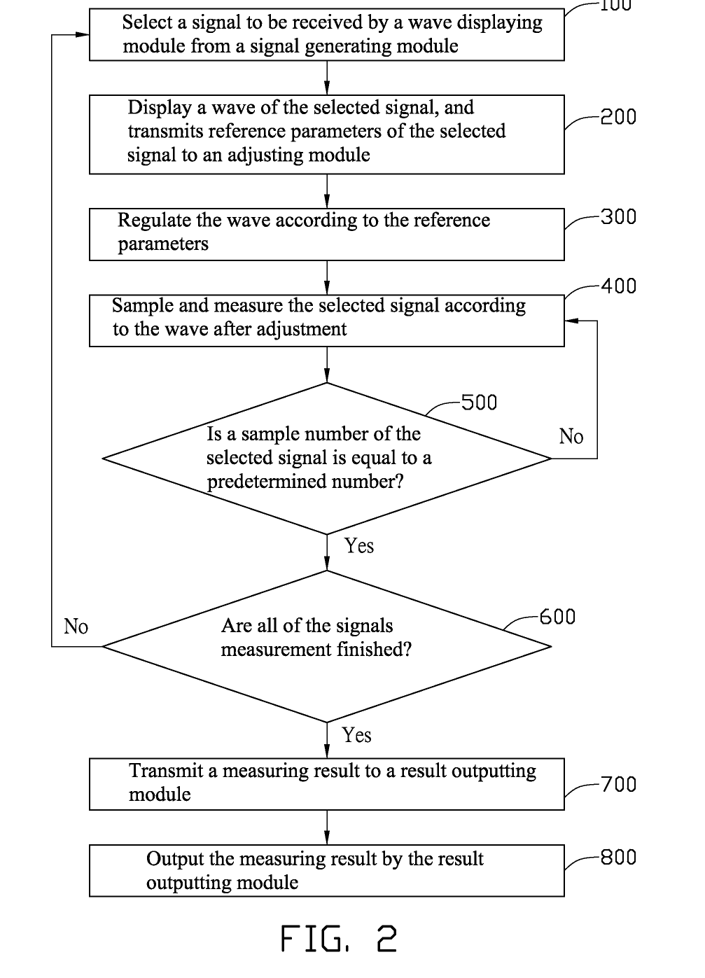

FIG. 2 is a flowchart of one embodiment of a signal measuring method. The method of FIG. 2 may be used to determine characteristics of signals to be measured. Depending on the embodiment, additional blocks may be added, others deleted, and the ordering of the blocks may be changed.

In block 100, the operating system is operated to control the channel selecting module 32 to turn on one of the signal channels C1, C2 . . . Cn. For example, when the signal channel C1 is turned on, the wave displaying module 20 receives a corresponding signal via the signal channel C1. The signal is selected by clicking corresponding signal selecting buttons on a user interface of the operating system.

In block 200, the wave displaying module 20 displays a wave of the received signal, and transmits reference parameters of the selected signal to the adjusting module 34. The reference parameters may be period, peak voltage etc. of the selected signal.

In block 300, the adjusting module 34 regulates the wave displayed on the oscilloscope 20, such as a position and a resolution of the wave according to the reference parameters.

In block 400, the measuring module 36 may sample and measure predetermined characteristics of the selected signal according to a user selected control button on the user interface. Measuring may, for example, include reading a minimum input high level voltage and a maximum input low level voltage of the selected signal.

In block 500, the measuring module 36 determines whether the predetermined of samples has been taken. If the predetermined of samples has been taken, block 600 is executed. Otherwise, if the predetermined of samples has not been taken, the flow returns to block 400.

In block 600, the measuring module 36 determines whether all of the signals to be sampled and measured have been sampled and measured. If all of the signals to be sampled and measured have been sampled and measured, block 700 is executed. Otherwise, if any of the signals to be sampled and measured have not been sampled and measured, the flow returns to block 100.

In block 700, the measuring module 36 transmits measuring results of each signal to the result outputting module 38.

In block 800, the outputting module 38 processes the measuring results of all of the signals, and shows the measuring results via a display screen of the computer system. The measuring results may be displayed in a form of graphs or tables. The quality of the measured signals can be determined by reading the measuring results.

The foregoing description of the exemplary embodiments of the disclosure has been presented only for the purposes of illustration and description and is not intended to be exhaustive or to limit the disclosure to the precise forms disclosed. Many modifications and variations are possible in light of the above everything. The embodiments were chosen and described in order to explain the principles of the disclosure and their practical application so as to enable others of ordinary skills in the art to utilize the disclosure and various embodiments and with various modifications as are suited to the particular use contemplated. Alternative embodiments will become apparent to those of ordinary skills in the art to which the present disclosure pertains without departing from its spirit and scope. Accordingly, the scope of the present disclosure is defined by the appended claims rather than the foregoing description and the exemplary embodiments described therein.

What is claimed is:

1. A signal measurement system comprising:
a signal generating module configured for generating signals;
a wave displaying module configured for receiving the signals and displaying wave graphs of the signals; and
a controlling module comprising:
an adjusting module configured for adjusting properties of the wave graphs;
a measuring module configured for measuring properties of the signals according to corresponding wave graphs; and
a result outputting module configured for receiving measurement results of the signals from the measuring module, and displaying the measurement results.

2. The signal measurement system as claimed in claim 1, further comprising a plurality of signal channels, wherein the wave displaying module is connected to the signal generating module via the signal channels.

3. The signal measurement system as claimed in claim 2, wherein the controlling module further comprises a channel selecting module, configured for selecting one of the signal channels to transmit a generated signal from the signal generating module to the wave displaying module.

4. The signal measurement system as claimed in claim 3, wherein the controlling module is set in a computer system, the channel selecting module, the adjusting module, and the result outputting module are controlled via an operating system of the computer system.

5. The signal measurement system as claimed in claim 4, wherein the result outputting module displays the measurement results in a form of table on a screen of the computer system.

6. The signal measurement system as claimed in claim 4, wherein the result outputting module displays the measurement results in a form of graphs on a screen of the computer system.

7. The signal measurement system as claimed in claim 1, wherein the wave displaying module is an oscilloscope.

8. The signal measurement system as claimed in claim 1, wherein the measurement results are parameter values of the signals.

9. A signal measurement method comprising:
receiving a signal from a signal generating module by a wave displaying module;
displaying a wave of the signal, and transmitting a reference parameter of the signal to an adjusting module;
adjusting properties of the wave according to the reference parameter;
measuring properties of the signal according to the wave after adjustment by a measuring module;
transmitting a measurement result of the signal to a result outputting module; and
displaying the measurement result by the result outputting module.

10. The signal measurement method as claimed in claim 9, further comprising: determining whether a sample number of the signal is equal to a predetermined number, wherein, the step of displaying the measurement result by the result outputting module is executed if the sample number is equal to the predetermined number, and, return to the step of measuring the signal according to the wave after adjustment if the sample number is not equal to the predetermined number.

11. The signal measurement method of claim 9, further comprising controlling the adjusting module, the measuring module, and the result outputting module via an user interface of a computer system.

12. A signal measurement method comprising:
generating a plurality of signals by a signal generating module;
selecting one of the signals from the signal generating module by a wave displaying module;
displaying a wave of the selected signal;
adjusting properties of the wave by an adjusting module;
measuring properties of the selected signal according to the wave after adjustment by a measuring module; and
determining whether all of the signals measurements are finished;
wherein upon a condition that all of the signals measurements are finished, the measuring module transmitting a measurement result of the selected signal to a result outputting module, and the result outputting module displaying the measurement result;
if any of the signals measurements is not finished, return to the selecting step.

13. The signal measurement method of claim 12, further comprising transmitting a reference parameter of the selected signal to the adjusting module by the wave displaying module, wherein the wave is adjusted according to the reference parameter.

14. The signal measurement method of claim 12, further comprising determining whether a sample number of the selected signal is equal to a predetermined number, wherein, the step of determining whether all of the signals measurements is executed if the sample number is equal to the predetermined number, and, return to the measuring step if the sample number is not equal to the predetermined number.

15. The signal measurement method of claim 12, wherein the signals are transmitted from the signal generating module to the wave displaying module via signal channels.

16. The signal measurement method of claim 15, wherein the selecting module further comprises turning on a signal channel corresponding to the selected signal by a channel selecting module.

17. The signal measurement method of claim 1 6, wherein the channel selecting module, the adjusting module, the measuring module, and the result outputting module are controlled via an user interface of a computer system.
